(19) United States
(12) Patent Application Publication
(10) Pub. No.: US 2025/0015561 A1
(43) Pub. Date: Jan. 9, 2025

(54) METHOD FOR PRODUCING A MULTIPLICITY OF VERTICALLY EMITTING SEMICONDUCTOR LASER DIODES AND VERTICALLY EMITTING SEMICONDUCTOR LASER DIODE

(71) Applicant: ams-OSRAM International GmbH, Regensburg (DE)

(72) Inventors: Norwin VON MALM, Nittendorf (DE); Hubert HALBRITTER, Dietfurt (DE)

(73) Assignee: ams-OSRAM International GmbH, Regensburg (DE)

(21) Appl. No.: 18/708,399

(22) PCT Filed: Nov. 2, 2022
(86) PCT No.: PCT/EP2022/080544

§ 371 Date: May 8, 2024

(30) Foreign Application Priority Data
Nov. 10, 2021 (DE) 10 2021 129 251.4

(51) Int. Cl. H01S 5/183; H01S 5/02

(52) U.S. Cl. CPC H01S 5/183; H01S 5/0216; H01S 5/0217

(57) ABSTRACT

The invention relates to a method for producing a multiplicity of vertically emitting semiconductor laser diodes, including providing a growth substrate, epitaxially growing an epitaxial semiconductor layer sequence including an active layer for generating electromagnetic radiation and including a sacrificial layer, wherein the sacrificial layer is disposed between the growth substrate and the active layer, forming trenches in the semiconductor layer sequence, resulting in a multiplicity of semiconductor layer stacks being formed and portions of the sacrificial layer being exposed, applying a carrier onto the epitaxial semiconductor layer sequence, and detaching the growth substrate by electrochemically etching the sacrificial layer, wherein an electrochemical etchant has access to the sacrificial layer through a cut-out in the growth substrate and/or through a cavity in the carrier. The invention also relates to a vertically emitting semiconductor laser diode.

### CROSS-REFERENCE TO RELATED APPLICATIONS

The present application is a national stage entry from International Application No. PCT/EP2022/080544, filed on Nov. 2, 2022, published as International Publication No. WO 2023/083664 A1 on May 19, 2023, and claims priority to German Patent Application No. 10 2021 129 251.4, filed Nov. 10, 2021, the disclosures of all of which are hereby incorporated by reference in their entireties.

### FIELD

A method for producing a multiplicity of vertically emitting semiconductor laser diodes and a vertically emitting semiconductor laser diode are disclosed.

### BACKGROUND

The publication J. Ciers et al, Appl. Phys. Lett. 118, 062107 (2021), describes the production of a smooth GaN membrane by electrochemical etching.

An improved method for producing a multiplicity of vertically emitting semiconductor laser diodes in a wafer compound is to be disclosed, wherein in particular a length of an optical cavity can be precisely adjusted. This object is solved by a method comprising the steps of claim 1.

Further, an improved vertically emitting laser diode comprising a precisely adjusted length of the optical cavity is to be disclosed. This object is solved by the subject-matter of claim 15.

Advantageous embodiments and further developments of the method for producing a multiplicity of vertically emitting semiconductor laser diodes and the vertically emitting semiconductor laser diode are specified in the dependent claims.

### SUMMARY

According to one embodiment of the method for producing a multiplicity of vertically emitting semiconductor laser diodes, a growth substrate is first provided. The growth substrate comprises, for example, sapphire, silicon carbide or preferably gallium nitride, or consists of one of these materials.

In particular, the growth substrate is a wafer, for example with a diameter of at least 2 inches. Compared to wafers with a smaller diameter, the production process of a multiplicity of vertically emitting semiconductor laser diodes on wafers with a larger diameter is generally more cost-effective.

According to a further embodiment of the method, an epitaxial semiconductor layer sequence is epitaxially grown on the growth substrate. The epitaxial semiconductor layer sequence comprises, for example, a III-V compound semiconductor material, in particular a nitride compound semiconductor material, which is deposited on the growth substrate, for example, by means of metal-organic vapor phase epitaxy.

Nitride compound semiconductor materials are compound semiconductor materials containing nitrogen, such as materials from the system InₓAl_{y}Ga_{1-x-y}N with 0≤x≤1, 0≤y≤1 and x+y≤1. For example, the nitride compound semiconductor material is gallium nitride, where x=0 and y=0, or aluminum gallium nitride, where x=0 and 0≤y≤1, or aluminum nitride, where x=0 and y=1.

According to a further embodiment of the method, the epitaxial semiconductor layer sequence comprises an active layer for generating electromagnetic radiation and a sacrificial layer, wherein the sacrificial layer is arranged between the growth substrate and the active layer. The active layer comprises at least a p-doped semiconductor region and an n-doped semiconductor region, and preferably comprises a single quantum well structure or a multiple quantum well structure.

The terms single quantum well structure and multiple quantum well structure include in particular any structure in which charge carriers can undergo a quantization of their energy states due to confinement. In particular, the term quantum well structure does not include any indication of the dimensionality of the quantization. It thus includes, inter alia, quantum wells, quantum wires and quantum dots and any combination of these structures.

In particular, the sacrificial layer comprises an n-doped semiconductor material, for example silicon doped gallium nitride. A silicon concentration in the sacrificial layer is, for example, between 10¹⁸ silicon atoms per cubic centimeter and 10²⁰ silicon atoms per cubic centimeter, inclusive, preferably between 5*10¹⁸ and 5*10¹⁹.

The sacrificial layer is configured to be able to precisely detach the growth substrate from the epitaxial semiconductor layer sequence. In particular, the sacrificial layer is dissolved by electrochemical etching, whereby the growth substrate is detached and the remaining epitaxial semiconductor layer sequence has a thickness that is as precisely defined as possible.

According to a further embodiment of the method, trenches are formed in the epitaxial semiconductor layer sequence, whereby a multiplicity of semiconductor layer stacks are formed and sub-regions of the sacrificial layer are exposed. The trenches are produced, for example, by a multi-stage mesa etching process. In this process, the epitaxial semiconductor layer sequence is preferably patterned and electrically contacted for further producing a multiplicity of semiconductor chips. In particular, the sacrificial layer is made accessible to an electrochemical etchant via the exposed sub-regions. This allows the semiconductor layer stacks to be underetched at the sacrificial layer in a later process step.

According to a further embodiment of the method, a carrier is applied onto the epitaxial semiconductor layer sequence. In particular, the carrier is arranged on a main surface of the epitaxial semiconductor layer sequence facing away from the growth substrate. The carrier comprises, for example, a metal, a ceramic or silicon. The carrier can be configured for heat dissipation and/or for electrical contacting of the vertically emitting semiconductor laser diodes. Optionally, the carrier can also contain electronic circuits, for example driver circuits for controlling and operating the semiconductor laser diodes or circuits for detecting electromagnetic radiation.

According to a further embodiment of the method, the growth substrate is detached by electrochemical etching of the sacrificial layer, wherein the sacrificial layer is accessible to an electrochemical etchant through a cut-out in the growth substrate and/or through a cavity in the carrier.

During electrochemical etching, the growth substrate with the epitaxial semiconductor layer sequence and the carrier arranged thereon is placed in a liquid electrochemical etchant. In particular, the electrochemical etchant is an electrolyte and comprises, for example, nitric acid. The sacrificial layer is connected to a positive pole of an electrical voltage source via an electrical contact, whereas a negative pole of the electrical voltage source is connected to an electrode located inside the electrochemical etchant. The electrode comprises graphite or consists of graphite, for example. An electrical voltage difference between the sacrificial layer and the electrode leads to an electrical current, whereby the sacrificial layer is decomposed by a combination of electrical and chemical processes. The etching rate depends, for example, on the applied electrical voltage difference and on the silicon concentration in the sacrificial layer.

In order to bring the liquid electrochemical etchant into direct contact with the sacrificial layer, at least one cut-out is formed into the growth substrate, for example. The cut-out preferably completely penetrates the growth substrate from a first main surface to a second main surface of the growth substrate. In other words, the cut-out forms a continuous hole in the growth substrate. The liquid electrochemical etchant can penetrate through the cut-out, in particular into trenches in the semiconductor layer sequence, where it can come into direct contact with the exposed sub-regions of the sacrificial layer.

Alternatively or additionally, the carrier can comprise cavities which completely penetrate the carrier from one side surface to an opposite side surface of the carrier. In particular, the cavities are configured to introduce the liquid electrochemical etchant into the trenches of the epitaxial semiconductor layer sequence, where the electrochemical etchant has a direct contact with the exposed sub-regions of the sacrificial layer. The cavities are formed, for example, by an etching process in the carrier and/or by partial sawing of the carrier.

According to a preferred embodiment, the method for producing a multiplicity of vertically emitting semiconductor laser diodes comprises the following steps:
providing a growth substrate,
epitaxially growing an epitaxial semiconductor layer sequence comprising an active layer for generating electromagnetic radiation and a sacrificial layer, wherein the sacrificial layer is arranged between the growth substrate and the active layer,
forming trenches in the semiconductor layer sequence, whereby a multiplicity of semiconductor layer stacks are formed and sub-regions of the sacrificial layer are exposed,
applying a carrier onto the epitaxial semiconductor layer sequence,
detaching the growth substrate by electrochemical etching of the sacrificial layer, wherein the sacrificial layer is accessible to an electrochemical etchant through a cut-out in the growth substrate and/or through a cavity in the carrier.

These steps are preferably carried out in the order indicated.

An idea of the method described herein is to produce a large number of vertically emitting semiconductor laser diodes based on a nitride compound semiconductor material in a wafer compound. In conventional methods, the detachment of the growth substrate poses a problem. In particular, an epitaxial growth of reflective layer sequences in the epitaxial semiconductor layer sequence, for example in the form of a Bragg mirror, is very difficult for semiconductor laser diodes made from a nitride compound semiconductor material. One reason for this is the low refractive index contrast of the semiconductor materials in question. The growth substrate is therefore detached, for example, in order to be able to apply a mirror or a reflective layer sequence to an underside of the epitaxial semiconductor layer sequence. A laser detachment process for detaching the growth substrate is not suitable for growth substrates made of gallium nitride, in particular due to a lack of contrast. Therefore, the growth substrate is removed by a mechanical polishing process, for example. However, this does not allow to precisely adjust the thickness of the epitaxial semiconductor layer sequence. The thickness of the epitaxial semiconductor layer sequence determines, in particular, an optical length of an optical resonator of the semiconductor laser. The optical length of the optical resonator determines a wavelength of the optical amplification of electromagnetic radiation generated during operation. Precise control of the thickness of the epitaxial semiconductor layer sequence is therefore particularly advantageous in order to be able to set the wavelength accurately. In contrast to mechanical detachment methods, the growth substrate is precisely detached with the method described herein. Thus, the thickness of the epitaxial semiconductor layer sequence can be precisely adjusted.

A further problem in producing a multiplicity of vertically emitting semiconductor laser diodes in a wafer compound that comprise a nitride compound semiconductor material is the alignment of mirrors or mirrored layer sequences to one another, which form the optical resonator. In particular, a mechanical detachment of the growth substrate can lead to opposing main surfaces of the epitaxial semiconductor layer sequence, on which the mirrors are applied, for example, that are not aligned plane-parallel to each other. As a result, the two mirrors of the optical resonator may not be precisely aligned, which can have a negative impact on the operation of the semiconductor laser diode. By detaching the growth substrate using the method described herein, the main surfaces of the epitaxial semiconductor layer sequence can be aligned precisely plane-parallel to each other.

According to a further embodiment of the method, the cut-out in the growth substrate is directly adjacent to the trench in the epitaxial semiconductor layer sequence, such that the cut-out and the trench form a continuous void. This arrangement of the cut-outs above the trenches allows the liquid electrochemical etchant to penetrate into the continuous voids and come into direct contact with the sacrificial layer via the exposed sub-regions of the sacrificial layer.

According to a further embodiment of the method, the cut-out in the growth substrate is formed by sawing, etching and/or laser drilling. In order to avoid contamination of the epitaxial semiconductor layer sequence during the formation of the cut-outs, the wafer is preferably left closed from the outside. For example, previously formed cut-outs are temporarily covered during the formation of a cut-out. Furthermore, the growth substrate can be thinned before the cut-outs are formed, which advantageously simplifies and accelerates the formation of the cut-outs.

For example, a cut-out may be arranged above each trench so that the growth substrate is divided into separate parts, with a part of the separated growth substrate being arranged on each semiconductor layer stack. In particular, the separate parts are not directly connected to each other. These separated parts can be detached during the further method by electrochemical etching. Here, the sacrificial layer in each semiconductor layer stack must be electrically contacted separately or through the carrier.

According to a further embodiment of the method, the cut-outs are formed in the growth substrate such that the growth substrate remains as one continuous piece. In particular, the growth substrate is not divided into separate parts. Preferably, the cut-outs are arranged such that each semiconductor layer stack is accessible to the electrochemical etchant. For example, the cut-outs are formed as elongated, slit-like holes that only extend in a direction parallel to the trenches across the growth substrate, but do not completely dissect the growth substrate.

According to a further embodiment of the method, the cavity in the carrier is created by forming pillars in the carrier. Preferably, a cross-section of the pillar corresponds to the cross-section of a semiconductor layer stack. In particular, the carrier is applied aligned to the epitaxial semiconductor layer sequence so that exactly one pillar is arranged over exactly one semiconductor layer stack.

According to a further embodiment of the method, the pillars have a height of at most ⅔ of a thickness of the carrier. Preferably, the height of a pillar is not larger than ⅓ of the thickness of the carrier. In particular, a mechanical stability of the carrier should be ensured, while the height of the pillars is large enough to allow the electrochemical etchant to be introduced as easily as possible into the trenches of the epitaxial semiconductor layer sequence.

According to a further embodiment of the method, the cavity is directly adjacent to the trench, so that the cavity and the trench form a continuous void. Consequently, the electrochemical etchant can be introduced into the trenches of the epitaxial semiconductor layer sequence from the side surfaces of the carrier via the cavities. There, the electrochemical etchant comes into direct contact with the exposed sub-regions of the sacrificial layer.

According to a further embodiment of the method, the epitaxial semiconductor layer sequence comprises a current distribution layer between the growth substrate and the sacrificial layer, via which the sacrificial layer is electrically contacted during electrochemical etching. Preferably, the sacrificial layer has the same electrical potential in all semiconductor layer stacks during electrochemical etching. As a result, the etching rate of the sacrificial layer is the same in all semiconductor layer stacks. In particular, the current distribution layer has a high electrical conductivity and thus leads to an equalization of the electrical potential of the sacrificial layer across the entire growth substrate during electrochemical etching.

The current distribution layer comprises, for example, an n-doped semiconductor material, in particular n-doped gallium nitride. For example, the concentration of dopants in the current distribution layer can be between 10¹⁸ atoms per cubic centimeter and 10¹⁹ atoms per cubic centimeter, inclusive.

According to a further embodiment of the method, a passivation layer is applied at least to side surfaces of the semiconductor layer stacks before the carrier is applied. The passivation layer comprises, for example, a dielectric material and avoids, in particular, electrical short circuits of the active layer by subsequently applying a metallic contact layer.

According to a further embodiment of the method, at least one opening is formed in the passivation layer for exposing the sub-regions of the sacrificial layer. In particular, the sub-regions of the sacrificial layer are freed from the passivation layer in order to make the sub-regions of the sacrificial layer accessible to the electrochemical etchant. The opening in the passivation layer is created, for example, by a lithographic method in which a photoresist mask is applied to the passivation layer and the passivation layer is etched away in openings in the photoresist mask.

According to a further embodiment of the method, a first dielectric mirror is applied onto a first main surface of at least one semiconductor layer stack before the carrier is applied. The dielectric mirror is, for example, a Bragg mirror comprising an alternating sequence of a multiplicity of dielectric layers having a different refractive index. The refractive index difference is at least 0.5, preferably at least 1.0, particularly preferably at least 1.2. The dielectric mirror is configured to at least partially reflect electromagnetic radiation generated by the active layer during operation.

According to a further embodiment of the method, after detachment of the growth substrate, a second dielectric mirror is applied to a second main surface of at least one semiconductor layer stack, which forms an optical resonator with the first dielectric mirror. The active layer, in conjunction with the optical resonator, is configured for generating electromagnetic laser radiation. Electromagnetic laser radiation is generated by stimulated emission and, in contrast to electromagnetic radiation generated by spontaneous emission, generally has a very high coherence length, a very narrow spectral linewidth and/or a high degree of polarization.

According to a further embodiment of the method, the optical resonator has a length of at most 1000 nanometers. Preferably, the optical resonator has a maximum length between 700 nanometers, inclusive, and 800 nanometers, inclusive. The length of the optical resonator is determined, for example, by a distance between the two dielectric mirrors between which the epitaxial semiconductor layer sequence is arranged.

According to a further embodiment of the method, the epitaxial semiconductor layer sequence comprises a nitride compound semiconductor material.

According to a further embodiment of the method, the sacrificial layer has a thickness of at least 80 nanometers. In the context of this application, statements on thicknesses of layers of the epitaxial semiconductor layer sequence refer to an extension of the layer in growth direction of the epitaxial semiconductor layer sequence.

According to a further embodiment of the method, the sacrificial layer is electrically contacted via a single electrical contact on the growth substrate during the electrochemical etching. Thus, an electrical contact to the sacrificial layers in all semiconductor layer stacks is established via a single electrical contact. Since the sacrificial layer does not have to be electrically contacted separately in each semiconductor layer stack, electrochemical etching can thus be simplified.

A vertically emitting semiconductor laser diode is further disclosed. All features disclosed for the method for producing a multiplicity of vertically emitting semiconductor laser diodes can also be formed in the vertically emitting semiconductor laser diode, and vice versa.

According to an embodiment, the vertically emitting semiconductor laser diode comprises a semiconductor layer stack with an active layer for generating electromagnetic radiation. In particular, the active layer comprises a multiple quantum well structure.

According to an embodiment, the vertically emitting semiconductor laser diode comprises two dielectric mirrors arranged on opposite main surfaces of the semiconductor layer stack and forming an optical resonator. The main surfaces are configured for coupling electromagnetic radiation into the semiconductor layer stack and for coupling electromagnetic radiation out of the semiconductor layer stack. In particular, the main surfaces are aligned parallel to a main extension plane of the layers of the semiconductor layer stack and are perpendicular to the growth direction of the epitaxial layers of the semiconductor layer stack.

The two dielectric mirrors are, for example, Bragg mirrors comprising a multiplicity of alternating dielectric layers with different refractive indices. The dielectric mirrors are configured for at least partially reflecting electromagnetic radiation generated during operation. In conjunction with the optical resonator, the active layer is configured, in particular, to generate electromagnetic laser radiation.

According to a further embodiment of the vertically emitting semiconductor laser diode, a distance between the two dielectric mirrors is at most 1000 nanometers. Preferably, the maximum distance between the two dielectric mirrors is between 700 nanometers and 800 nanometers, inclusive.

According to a further embodiment of the vertically emitting semiconductor laser diode, the semiconductor layer stack is based on a nitride compound semiconductor material. For example, the vertically emitting semiconductor laser diode is configured to emit electromagnetic laser radiation in the blue and/or ultraviolet spectral range.

According to a further embodiment, the vertically emitting semiconductor laser diode is free of a growth substrate on which the semiconductor layer stack has been grown. In particular, the growth substrate is completely detached from the semiconductor layer stack. Thus, there is no growth substrate arranged between the two dielectric mirrors.

According to a further embodiment, the vertically emitting semiconductor laser diode comprises a carrier on which the semiconductor layer stack is arranged. In particular, the semiconductor layer stack is arranged on a main surface of the carrier. For example, a dielectric mirror is arranged between the main surface of the carrier and the semiconductor layer stack.

According to a further embodiment of the vertically emitting semiconductor laser diode, at least one side surface of the carrier has traces of a cavity. The traces of the cavity are, for example, surface structures in the side surface. The traces are formed, in particular, during the method for producing a multiplicity of vertically emitting semiconductor laser diodes, for example by sawing or etching the cavities into the carrier, or by forming pillars in the carrier. For example, the traces of the cavity extend in a direction parallel to the main surface of the carrier over the entire side surface. Furthermore, the traces of the cavity extend in a direction perpendicular to the main surface of the carrier, for example over at most ⅔ of the side surface of the carrier. In other words, the traces of the cavity extend over at most ⅔ of the thickness of the carrier.

Further advantageous embodiments and further developments of the method for producing a multiplicity of vertically emitting semiconductor laser diodes and a vertically emitting semiconductor laser diode become apparent from the exemplary embodiments described below in conjunction with the figures.

### BRIEF DESCRIPTION OF THE DRAWINGS

FIGS. 1 to 11 show schematic cross-sectional views of various stages of a method for producing a multiplicity of vertically emitting semiconductor laser diodes according to an exemplary embodiment.

FIG. 12 shows a schematic top view of a growth substrate after a step of a method for producing a multiplicity of vertically emitting semiconductor laser diodes according to an exemplary embodiment.

FIGS. 13 to 15 show schematic cross-sectional views of stages of a method for producing a multiplicity of vertically emitting semiconductor laser diodes according to a further exemplary embodiment.

FIGS. 16 to 18 show schematic cross-sectional views of vertically emitting semiconductor laser diodes according to various exemplary embodiments.

### DETAILED DESCRIPTION

Elements that are identical, similar or have the same effect are marked in the figures with the same reference signs. The figures and the proportions of the elements shown in the figures should not be considered to be true to scale. Rather, individual elements, in particular layer thicknesses, may be shown exaggeratedly large for better visualization and/or better understanding.

In the method according to the exemplary embodiment shown in FIGS. 1 to 12, an epitaxial semiconductor layer sequence 2 is first grown epitaxially on a growth substrate 1 (FIG. 1). In particular, the growth substrate 1 is a wafer comprising gallium nitride or consisting of gallium nitride. The epitaxial semiconductor layer sequence 2 comprises a nitride compound semiconductor material and comprises an active layer 3 for generating electromagnetic radiation. The epitaxial semiconductor layer sequence 2 comprises at least one n-doped semiconductor region and at least one p-doped semiconductor region in a growth direction R. The active layer 3 comprises a multiple quantum well structure.

Further, the epitaxial semiconductor layer sequence 2 comprises a sacrificial layer 4 arranged between the active layer 3 and the growth substrate 1. The sacrificial layer 4 comprises silicon doped gallium nitride having a silicon concentration between 10¹⁹ silicon atoms per cubic centimeter and 10²⁰ silicon atoms per cubic centimeter, inclusive.

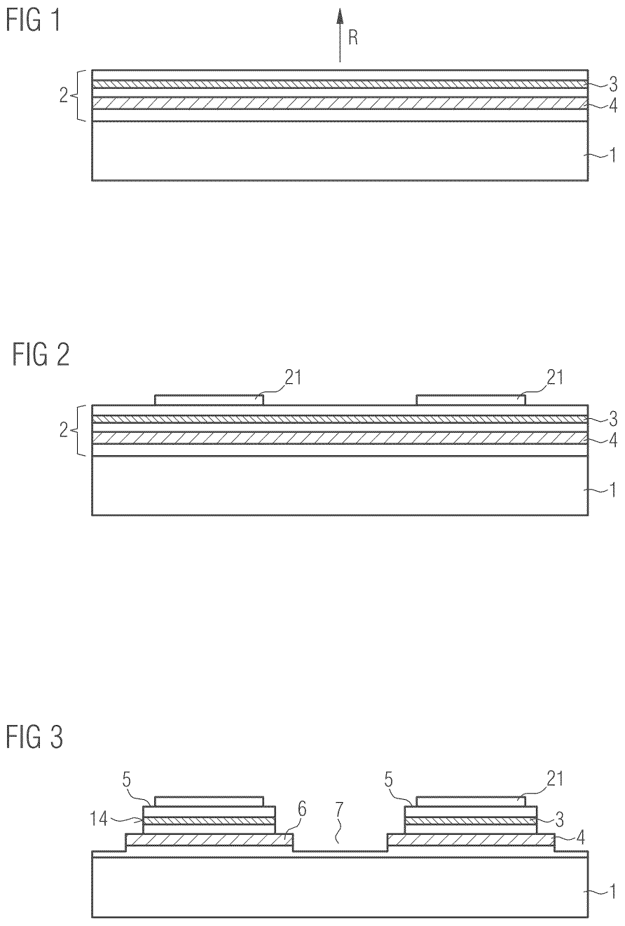

In a further process step, a multiplicity of p-contacts 21 are applied to the epitaxial semiconductor layer sequence 2 (FIG. 2). In particular, one p-contact 21 is applied for each vertically emitting semiconductor laser diode. The p-contacts 21 comprise a transparent conductive oxide, for example indium tin oxide (ITO), or n-doped gallium nitride, wherein a tunnel barrier is arranged between the n-doped gallium nitride and a p-doped semiconductor layer of the epitaxial semiconductor layer sequence 2.

FIG. 3 shows a schematic sectional view of the epitaxial semiconductor layer sequence 2 after a two-stage mesa etching process. In the two-step mesa etching process, trenches 7 are formed in the epitaxial semiconductor layer sequence 2, whereby the semiconductor layer sequence 2 is structured and comprises semiconductor layer stacks 5. Furthermore, sub-regions 6 of the sacrificial layer 4 are exposed in order to make the sacrificial layer 4 accessible to the electrochemical etchant in a later process step.

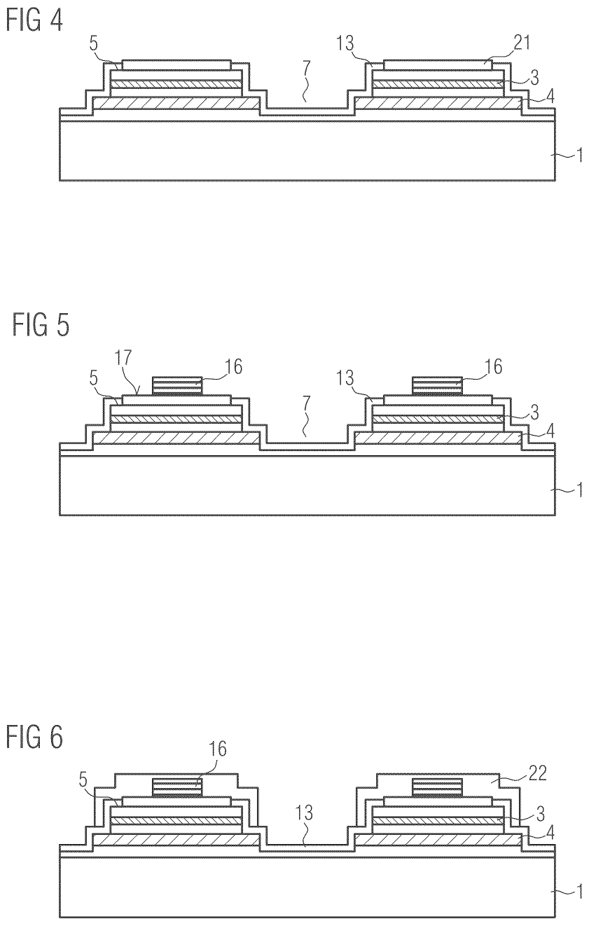

In a further process step, a passivation layer 13 is applied to the side surfaces 14 of the semiconductor layer stacks 5 and in the trenches 7 between the semiconductor layer stacks 5 (FIG. 4). In particular, the passivation layer 13 is electrically insulating and comprises, for example, a dielectric material. The p-contacts 21 remain free of the passivation layer 13.

In a further process step, first dielectric mirrors 16 are applied to the p-contacts 21 of the semiconductor layer stacks 5 (FIG. 5). In particular, the dielectric mirrors 16 are Bragg mirrors comprising a multiplicity of alternating dielectric layers with different refractive indices. The dielectric mirrors 16 are configured for at least partially reflecting electromagnetic radiation generated by the active layer 3 during operation.

In a further process step, a planarization layer 22 is applied to the semiconductor layer stacks 5 (FIG. 6). In particular, the planarization layer 22 comprises a metal which is configured for soldering electrical connections and thus for electrically contacting the semiconductor layer stacks 5, for example.

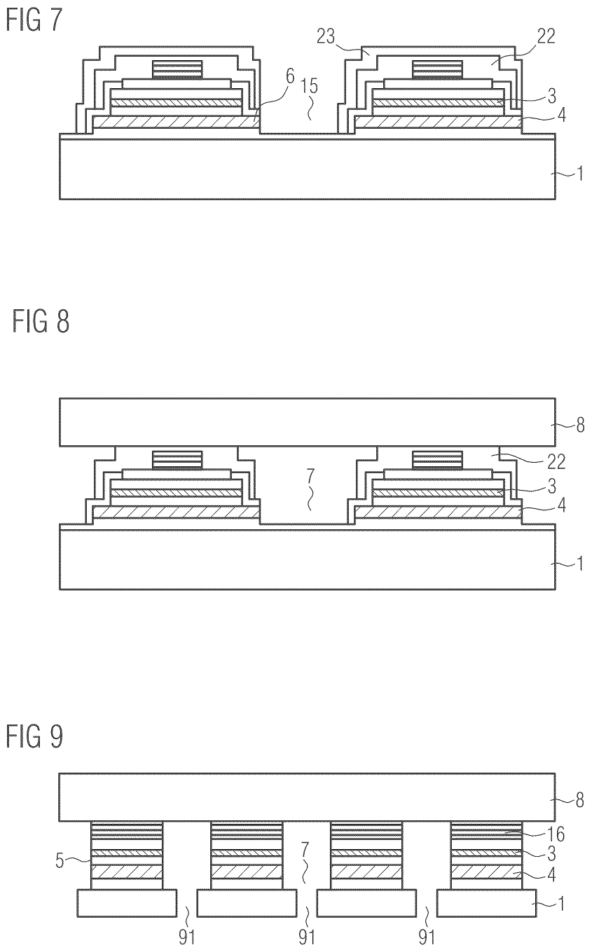

In a further process step, an opening 15 is formed in the passivation layer 13 in order to expose the sub-regions 6 of the sacrificial layer 4 (FIG. 7). In particular, this is done by means of a lithographic method in which a photoresist mask 23 is applied and exposed in certain areas. Unexposed areas of the photoresist mask 23 are then removed, for example. Subsequently, parts of the passivation layer 13 that are not covered by the photoresist mask 23 are removed by an etching process.

In a further process step, the photoresist mask 23 is completely removed and a carrier 8 is mounted onto the semiconductor layer stacks 5 (FIG. 8). The carrier 8 comprises, for example, silicon, a ceramic or a metal and can be configured to dissipate heat generated during operation of the vertically emitting semiconductor laser diodes. Furthermore, the carrier 8 is configured, for example, for electrical contacting of the semiconductor layer stacks 5. The carrier 8 can, for example, comprise two wafers made of silicon, a metal or an aluminum nitride ceramic that are connected over their entire surface, with the first wafer being partially sawn.

In a further process step, the growth substrate 1 is thinned and a multiplicity of cut-outs 91 are formed in the growth substrate 1 (FIG. 9). In order to simplify the illustration and make it clearer, the semiconductor layer stacks 5 are shown in simplified form compared to FIG. 8. However, the semiconductor layer stacks 5 of FIG. 9 comprise the same structure as the semiconductor layer stacks 5 of FIG. 8.

The growth substrate 1 can be thinned, for example, by mechanical polishing or a mechanical removal process. The cut-outs 91 are formed in the growth substrate 1 by sawing, laser drilling or a directed etching process, for example a dry etching process, in particular a plasma etching process. In particular, the cut-outs 91 are arranged above the trenches 7 between the semiconductor layer stacks 5. As a result, a liquid electrochemical etchant, for example nitric acid, can penetrate into the trenches 7 between the semiconductor layer stacks 5 via the cut-outs 91 in a subsequent process step and come into direct contact with the sacrificial layer 4 there.

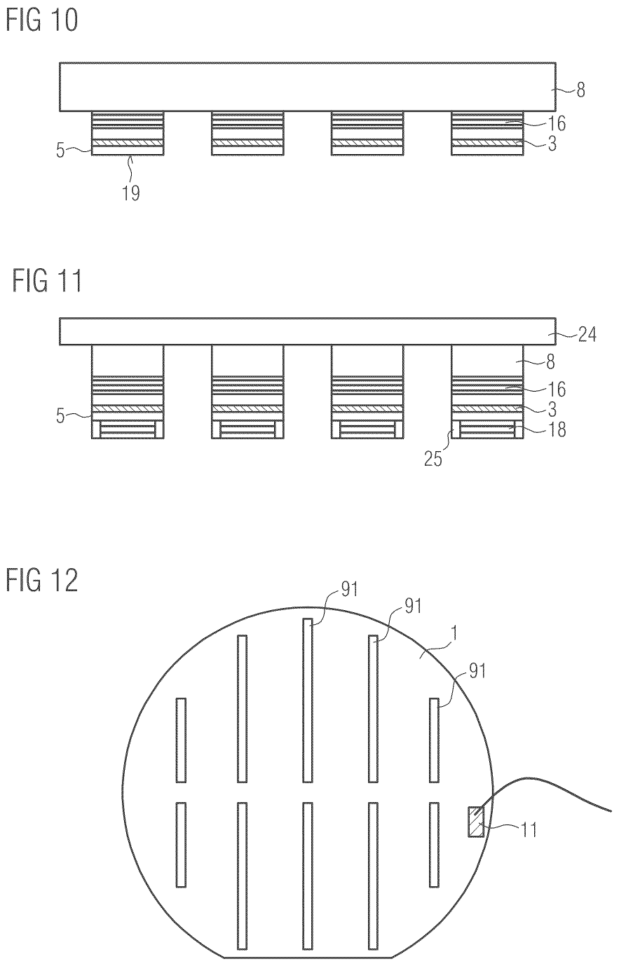

In a further process step, the growth substrate 1 is detached from the semiconductor layer stacks 5 by electrochemical etching (FIG. 10). During electrochemical etching, the growth substrate 1 with the epitaxially grown and already structured semiconductor layer sequence 2 and the carrier 8 applied thereto is placed in a bath with a liquid electrochemical etchant. The sacrificial layer 4 is electrically contacted and connected to the positive pole of an electrical voltage source. The negative pole of the electrical voltage source is connected to an electrode that is in direct contact with the liquid electrochemical etchant.

In particular, through the cut-outs 91 in the growth substrate 1, the electrochemical etchant is in direct contact with the sacrificial layer 4. By applying an electrical voltage difference between the sacrificial layer 4 and the electrode, the sacrificial layer 4 decomposes, causing the growth substrate 1 to detach. The etching rate of the sacrificial layer is determined by the applied electrical voltage difference between the sacrificial layer 4 and the electrode, as well as by the silicon concentration of the sacrificial layer 4.

In a further process step, second dielectric mirrors 18 are applied to second main surfaces 19 of the epitaxial semiconductor layer sequence (FIG. 11). Together with the first dielectric mirrors 16, the second dielectric mirrors 18 each form an optical resonator in which the active layer 3 is arranged. Furthermore, n-contacts 25 for electrically contacting the semiconductor layer sequence 25 are applied to the second main surfaces 19. Subsequently, a film 24, which is configured as a temporary carrier, is applied to the carrier 8 and the semiconductor layer stacks 5 are singulated to produce a multiplicity of semiconductor chips, the singulation being performed, for example, by sawing the carrier 8.

FIG. 12 shows a schematic top view of a growth substrate 1 after a process step, wherein a multiplicity of cut-outs 91 are formed in the growth substrate 1. In particular, the growth substrate 1 remains connected and is not divided into separate regions. The cut-outs 91 are formed as slit-like holes in the growth substrate 1, which are arranged over trenches 7 in the semiconductor layer sequence 2. The growth substrate comprises a single electrical contact 11, via which the sacrificial layer 4 in all semiconductor layer stacks 5 is centrally electrically contacted for the electrochemical etching process.

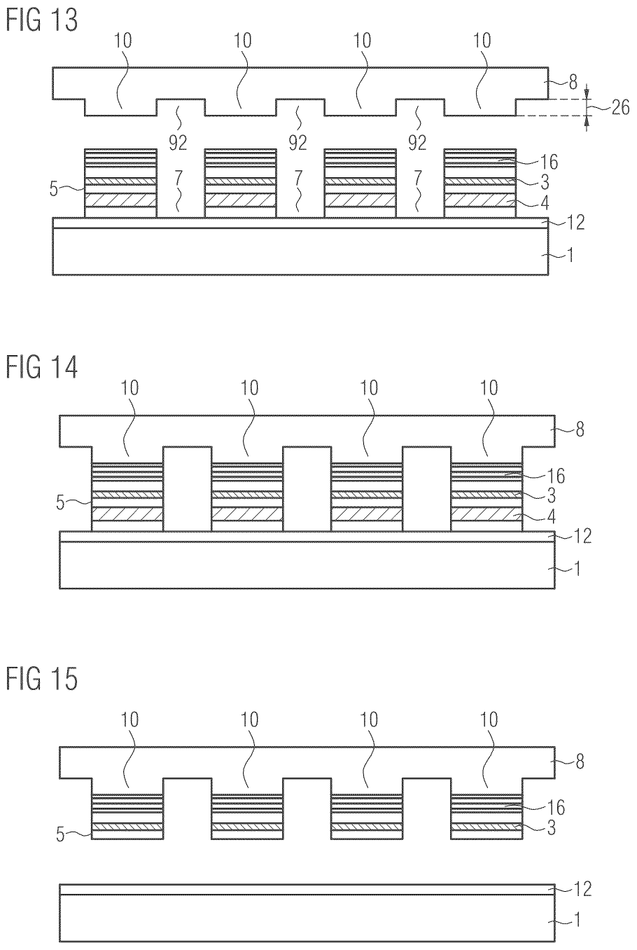

FIGS. 13 to 15 show schematic sectional views after process steps according to a further exemplary embodiment. In contrast to FIG. 8, the carrier 8 here comprises cavities 92 which extend from one side surface of the carrier 8 to an opposite side surface of the carrier 8. The arrangement of the cavities 92 forms a structure comprising a multiplicity of pillars 10 on the carrier 8, wherein a cross-section of a pillar 10 corresponds to a cross-section of a semiconductor layer stack 5. The pillars comprise a height 26 of at most ⅔ of a thickness of the carrier. The pillars 10 on the carrier 8 are aligned with the semiconductor layer stacks 5 (FIG. 13) before the carrier 8 is applied to the semiconductor layer stacks (FIG. 14). The electrochemical etchant penetrates through the cavities 92 into the trenches 7 between the semiconductor layer stacks 5, where it comes into direct contact with the exposed sub-regions 6 of the sacrificial layer 4. Subsequently, the growth substrate 1 is detached by electrochemical etching of the sacrificial layer 4 (FIG. 15). Here, the epitaxial semiconductor layer sequence 2 comprises an additional current distribution layer 12, which is arranged between the growth substrate 1 and the sacrificial layer 4. The current distribution layer 12 is configured to improve the electrical contacting of the sacrificial layer 4 for electrochemical etching. An advantage of this method is that the growth substrate 1 is not destroyed and can therefore be reused.

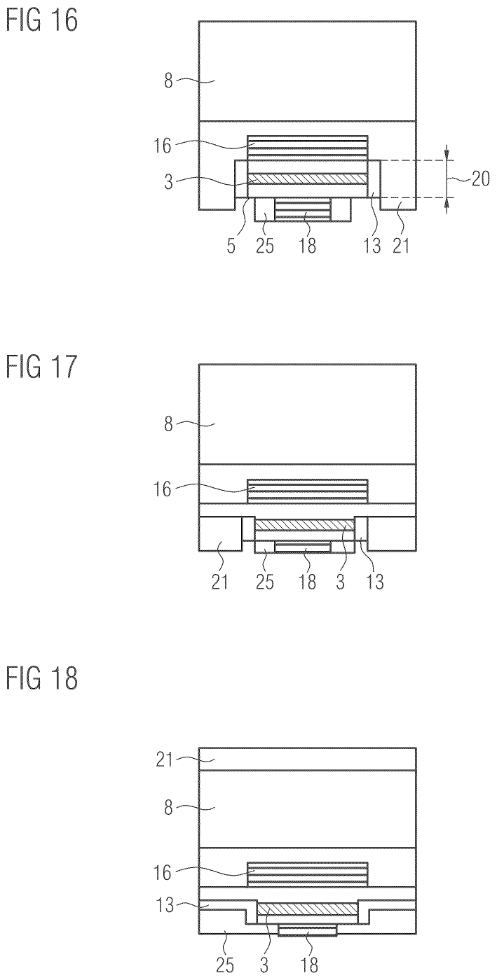

FIG. 16 shows a schematic sectional view of an exemplary embodiment of a vertically emitting semiconductor laser diode. Electrical contacting of an active layer 3 is achieved via a p-contact 21 and an n-contact 25, each of which comprises electrical connection areas on a side of the semiconductor laser diode facing away from a carrier 8, with a passivation layer 13 being arranged between the semiconductor layer stack 5 and the p-contact 21.

In this exemplary embodiment, in particular a p-doped semiconductor region of the semiconductor layer stack 5 facing the carrier 8 is structured by a two-stage mesa etching process. In particular, the structuring of the semiconductor layer stack 5 by the two-stage mesa etching process is carried out before detachment of the growth substrate 1 and before arranging the epitaxial semiconductor layer sequence 2 on the carrier 8.

The active layer 3 is arranged between two dielectric mirrors 16, 18, wherein the two dielectric mirrors 16, 18 are disposed on opposite main surfaces 17, 19 of the semiconductor layer stacks 5. In particular, the growth substrate 1 is completely removed and there are no parts of a growth substrate 1 between the dielectric mirrors 16, 18. A distance 20 between the dielectric mirrors is at most 1000 nanometers. In other words, the two dielectric mirrors 16, 18 are arranged in direct contact with the epitaxial semiconductor layer stack.

FIG. 17 shows a schematic sectional view of a further exemplary embodiment of a vertically emitting semiconductor laser diode. In contrast to FIG. 16, here an n-doped semiconductor region facing away from the carrier 8 is structured by a mesa etching process. In contrast to the exemplary embodiment in FIG. 16, the structuring of the semiconductor layer stack 5 is carried out in particular after detachment of the growth substrate 1.

FIG. 18 shows a schematic sectional view of a further exemplary embodiment of a vertically emitting semiconductor laser diode. Here, in contrast to FIG. 17, the p-contact 21 is arranged on a side of the carrier 8 facing away from the semiconductor layer stack 5.

The invention is not limited to the exemplary embodiments by the description thereof. Rather, the invention includes any new feature as well as any combination of features, which includes in particular any combination of features in the patent claims, even if this feature or combination itself is not explicitly stated in the patent claims or exemplary embodiments.

1. A method for producing a multiplicity of vertically emitting semiconductor laser diodes comprising:
providing a growth substrate,
epitaxially growing an epitaxial semiconductor layer sequence comprising an active layer for generating electromagnetic radiation and a sacrificial layer, wherein the sacrificial layer is arranged between the growth substrate and the active layer,
forming trenches in the semiconductor layer sequence, whereby a multiplicity of semiconductor layer stacks are formed and sub-regions of the sacrificial layer are exposed,
applying a carrier onto the epitaxial semiconductor layer sequence, and
detaching the growth substrate by electrochemical etching of the sacrificial layer, wherein the sacrificial layer is accessible to an electrochemical etchant through a cut-out in the growth substrate and/or through a cavity in the carrier.

2. The method according to claim 1, wherein the cut-out is directly adjacent to the trench, such that the cut-out and the trench form a continuous void.

3. The method according to claim 1, wherein the cut-out in the growth substrate is formed by sawing, etching and/or laser drilling.

4. The method according to claim 1, wherein the cavity in the carrier is created by forming pillars in the carrier.

5. The method according to claim 4, wherein the pillars have a height of at most ⅔ of a thickness of the carrier.

6. The method according to claim 1, wherein the cavity is directly adjacent to the trench, so that the cavity and the trench form a continuous void.

7. The method according to claim 1, wherein the epitaxial semiconductor layer sequence comprises a current distribution layer between the growth substrate and the sacrificial layer, via which the sacrificial layer is electrically contacted during electrochemical etching.

8. The method according to claim 1, wherein
a passivation layer is applied at least to side surfaces of the semiconductor layer stacks before the carrier is applied, and
at least one opening is formed in the passivation layer for exposing the sub-regions of the sacrificial layer.

9. The method according to claim 1, wherein a first dielectric mirror is applied onto a first main surface of at least one semiconductor layer stack before the carrier is applied.

10. The method according to claim 9, wherein after detaching the growth substrate, a second dielectric mirror is applied to a second main surface of at least one semiconductor layer stack, which forms an optical resonator with the first dielectric mirror.

11. The method according to claim 10, wherein the optical resonator has a length of at most 1000 nanometers.

12. The method according to claim 1, wherein the epitaxial semiconductor layer sequence comprises a nitride compound semiconductor material.

13. The method according to claim 1, wherein the sacrificial layer has a thickness of at least 80 nanometers.

14. The method according to claim 1, wherein the sacrificial layer is electrically contacted via a single electrical contact on the growth substrate during the electrochemical etching.

15. A vertically emitting semiconductor laser diode comprising:
a semiconductor layer stack with an active layer for generating electromagnetic radiation, and
two dielectric mirrors arranged on opposite main surfaces of the semiconductor layer stack and forming an optical resonator, wherein
a distance between the two dielectric mirrors is at most 1000 nanometers, and
the semiconductor layer stack is based on a nitride compound semiconductor material.

16. The vertically emitting semiconductor laser diode according to claim 15, which is free of a growth substrate for the semiconductor layer stack.
